(19) United States
(12) Patent Application Publication
(10) Pub. No.: US 2026/0090022 A1
(43) Pub. Date: Mar. 26, 2026

(54) ISOLATION INTERFACES AT THE ENDS OF FIN ISOLATION REGIONS

(71) Applicant: Taiwan Semiconductor Manufacturing Co., Ltd., Hsinchu (TW)

(72) Inventors: Chao-Hsuan Chen, Hsinchu (TW); I-Wei Yang, Yilan County (TW); Po-Ting Chiu, Hsinchu (TW); Bo-Hong Chen, Kaohsiung City (TW); Shu-Yuan Ku, Zhubei City (TW); Ryan Chia-Jen Chen, Hsinchu (TW)

(21) Appl. No.: 18/891,770

(22) Filed: Sep. 20, 2024

(51) Int. Cl. H01L 29/423; H01L 21/762; H01L 21/8234; H01L 27/088; H01L 29/06; H01L 29/08; H01L 29/66; H01L 29/775; H01L 29/786

(52) U.S. Cl. CPC H10D 30/6735; H10D 30/014; H10D 30/43; H10D 30/6757; H10D 62/121; H10D 62/151; H10D 64/017; H10D 84/0151; H10D 84/038; H10D 84/83; H10W 10/014; H10W 10/17

(57) ABSTRACT

A method that include forming a plurality of semiconductor regions having first lengthwise directions parallel to a first direction, and forming a plurality of gate stacks having second lengthwise directions parallel to a second direction perpendicular to the first direction, wherein the plurality of gate stacks are on first portions of the plurality of semiconductor regions. The method can also include etching the plurality of semiconductor regions to form a first plurality of openings, and filling the first plurality of openings with a first dielectric material to form fin isolation regions. The method can also include forming an isolation interface region between the fin isolation regions and the gate stacks.

### BACKGROUND

Technological advances in Integrated Circuit (IC) materials and design have produced generations of ICs where each generation has smaller and more complex circuits than the previous generations. In the course of IC evolution, functional density (for example, the number of interconnected devices per chip area) has generally increased while geometry sizes have decreased. This scaling down process generally provides benefits by increasing production efficiency and lowering associated costs.

Such scaling down has also increased the complexity of processing and manufacturing ICs, and for these advances to be realized, similar developments in IC processing and manufacturing are needed. For example, Gate-All-Around (GAA) Transistors have been introduced to replace planar transistors. The structures of the GAA transistors and methods of fabricating the GAA transistors are being developed.

The formation of the GAA transistors typically includes forming long strips (including alternating semiconductor materials) and long gate stacks, and then forming isolation regions to cut the long strips and long gate stacks into shorter portions. The shorter portions may be used to form the channel layers and the gate stacks of the GAA transistors.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-4, 5A, 5B, 6A, 6B, 7A, 7B, 8A, 8B, 9A, 9B, 10A, 10B, 10C, 11, 19A, 19B, 20A, 20B, 32A, 32B, 33A and 33B illustrate the views of intermediate stages in the formation of transistors in accordance with some embodiments.

FIGS. 12A, 12B, 13A, 13B, 14A, 14B, 15A, 15B, 16A, 16B, 17A, 17B, 18A and 18B illustrate the formation of Continuous Polysilicon on Diffusion edge (CPODE) regions by cutting dummy gate stacks in accordance with some embodiments.

FIGS. 21-26 illustrate the formation of cut-metal-gate regions in accordance with some embodiments.

FIGS. 27-31 illustrate forming Cut-Metal Gate (CMG) isolation interfaces in accordance with some embodiments.

FIG. 34 illustrates a process flow for forming transistors in accordance with some embodiments.

FIG. 35 is a top down view illustrating a Cut-Metal Gate (CMG) isolation interface in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Gate-All-Around (GAA) transistors, Cut-Metal-Gate (CMG) isolation regions, Continuous Polysilicon on Diffusion edge (CPODE) isolation regions, and the method of forming the same are provided. In some embodiments, the cut-metal gate isolation (CMG) regions are formed through the ends of the Continuous Polysilicon on Diffusion edge (CPODE) isolation regions. In some embodiments, by positioning the cut metal gate (CMG) isolation regions at the ends of the Continuous Polysilicon on Diffusion edge (CPODE) isolation regions, the methods and structures that are described herein can remove device leakage across the contacts to the source/drain regions (MD to MD device leakage). More particularly, leakage pathways between the contacts to source and drain regions (MD to MD device leakage pathways) that can present at the ends of the Continuous Polysilicon on Diffusion edge (CPODE) isolation regions abutting the metal gate can be removed using an etch step, e.g., cut metal gate (CMG) etch. In some embodiments, the leakage pathways between the contacts to source and drain regions (MD to MD device leakage pathways) result from metal gate (MG) refill processes for the replacement gate processes at locations adjacent to the Continuous Polysilicon on Diffusion edge (CPODE) isolation regions. In some instances, it has been determined that leakage pathways may be present at edges of CPODE regions having rounded profiles at the line ends. In some embodiments, the leakage pathways can be removed with a cut metal gate (CMG) dry etching process that removes the leakage pathway, and can trim the profile of the edge of the CPODE regions from having a rounded profile to a square profile. The method and structures described herein can reduce device leakage.

In the illustrated embodiments, the formation of GAA Transistors is used as an example to explain the concept of the present disclosure. Other types of transistors such as Fin Field-Effect Transistors (FinFETs), planar transistors, or the like may also adopt the concept of the present disclosure. Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

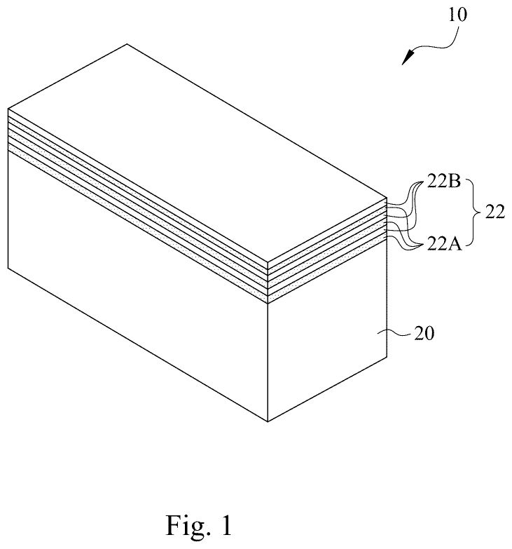

FIGS. 1-4, 5A, 5B, 6A, 6B, 7A, 7B, 8A, 8B, 9A, 9B, 10A, 10B, 10C, 11, 19A, 19B, 20A, and 20B illustrate the views of intermediate stages in the formation of transistors in accordance with some embodiments of the present disclosure.

Referring to FIG. 1, a perspective view of wafer 10 is shown. Wafer 10 includes a multilayer structure comprising multilayer stack 22 on substrate 20. In accordance with some embodiments, substrate 20 is a semiconductor substrate, which may be a silicon substrate, a silicon germanium (SiGe) substrate, or the like, while other substrates and/or structures, such as semiconductor-on-insulator (SOI), strained SOI, silicon germanium on insulator, or the like, could be used. Substrate 20 may be doped as a p-type semiconductor, although in other embodiments, it may be doped as an n-type semiconductor.

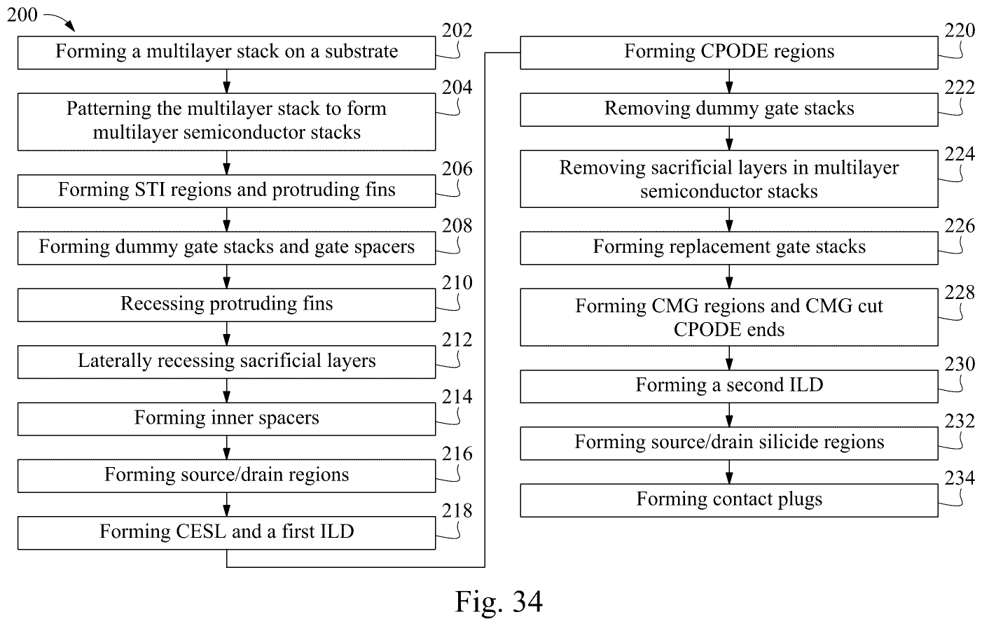

In accordance with some embodiments, multilayer stack 22 is formed through a series of deposition processes for depositing alternating materials. The respective process is illustrated as process 202 in the process flow 200 shown as in FIG. 34. In accordance with some embodiments, multilayer stack 22 comprises first layers 22A formed of a first semiconductor material and second layers 22B formed of a second semiconductor material different from the first semiconductor material.

In accordance with some embodiments, the first semiconductor material of a first layer 22A is formed of or comprises SiGe, Ge, Si, GaAs, InSb, GaSb, InAlAs, InGaAs, GaSbP, GaAsSb, or the like. In accordance with some embodiments, the deposition of first layers 22A (for example, SiGe) is through epitaxial growth, and the corresponding deposition method may be Vapor-Phase Epitaxy (VPE), Molecular Beam Epitaxy (MBE), Chemical Vapor deposition (CVD), Low Pressure CVD (LPCVD), Atomic Layer Deposition (ALD), Ultra High Vacuum CVD (UHVCVD), Reduced Pressure CVD (RPCVD), or the like. In accordance with some embodiments, the first layer 22A is formed to a first thickness in the range between about 30 Å and about 300 Å. However, any suitable thickness may be utilized while remaining within the scope of the embodiments.

Once the first layer 22A has been deposited over substrate 20, a second layer 22B is deposited over the first layer 22A. In accordance with some embodiments, the second layers 22B is formed of or comprises a second semiconductor material such as Si, SiGe, Ge, GaAs, InSb, GaSb, InAlAs, InGaAs, GaSbP, GaAsSb, combinations of these, or the like, with the second semiconductor material being different from the first semiconductor material of first layer 22A.

For example, in accordance with some embodiments in which the first layer 22A is silicon germanium, the second layer 22B may be formed of silicon, or vice versa. It is appreciated that any suitable combination of materials may be utilized for first layers 22A and the second layers 22B.

In accordance with some embodiments, the second layer 22B is epitaxially grown on the first layer 22A using a deposition technique similar to that is used to form the first layer 22A. In accordance with some embodiments, the second layer 22B is formed to a similar thickness to that of the first layer 22A. The second layer 22B may also be formed to a thickness that is different from the first layer 22A. In accordance with some embodiments, the second layer 22A has thickness in the range between about 4 nm and 7 nm, while the second layer 22B has thickness in the range between about 8 nm and 12 nm, for example.

Once the second layer 22B has been formed over the first layer 22A, the deposition process is repeated to form the remaining layers in multilayer stack 22, until a desired topmost layer of multilayer stack 22 has been formed. In accordance with some embodiments, first layers 22A have thicknesses the same as or similar to each other, and second layers 22B have thicknesses the same as or similar to each other. First layers 22A may also have the same thicknesses as, or different thicknesses from, that of second layers 22B. In accordance with some embodiments, first layers 22A are removed in the subsequent processes, and are alternatively referred to as sacrificial layers 22A throughout the description. In accordance with alternative embodiments, second layers 22B are sacrificial, and are removed in the subsequent processes.

In accordance with some embodiments, there may be some pad oxide layer(s) and hard mask layer(s) (not shown) formed over multilayer stack 22. These layers are patterned, and are used for the subsequent patterning of multilayer stack 22.

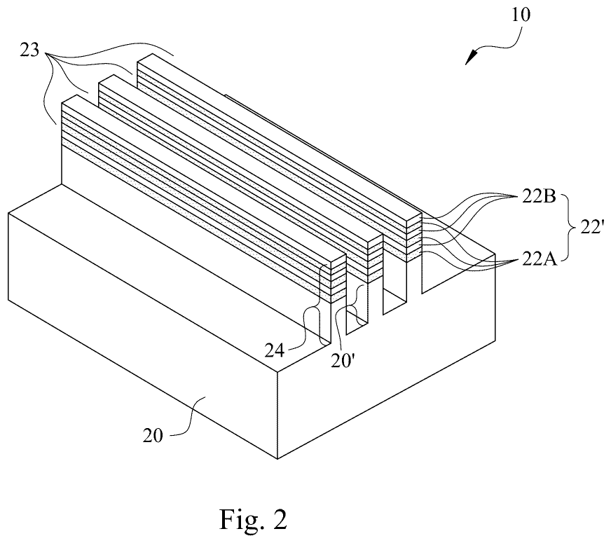

Referring to FIG. 2, multilayer stack 22 and a portion of the underlying substrate 20 are patterned in an etching process(es), so that trenches 23 are formed. Trenches 23 extend into substrate 20. The remaining portions of multilayer stacks are referred to as multilayer stacks 22′ hereinafter. Underlying multilayer stacks 22′, some portions of substrate 20 are left, and are referred to as substrate strips 20′ hereinafter. Multilayer stacks 22′ include semiconductor layers 22A and 22B. Semiconductor layers 22A are alternatively referred to as sacrificial layers, and semiconductor layers 22B are alternatively referred to as nanostructures hereinafter. The portions of multilayer stacks 22′ and the underlying substrate strips 20′ are collectively referred to as semiconductor strips 24.

In above-illustrated embodiments, the transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in an embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the device structure.

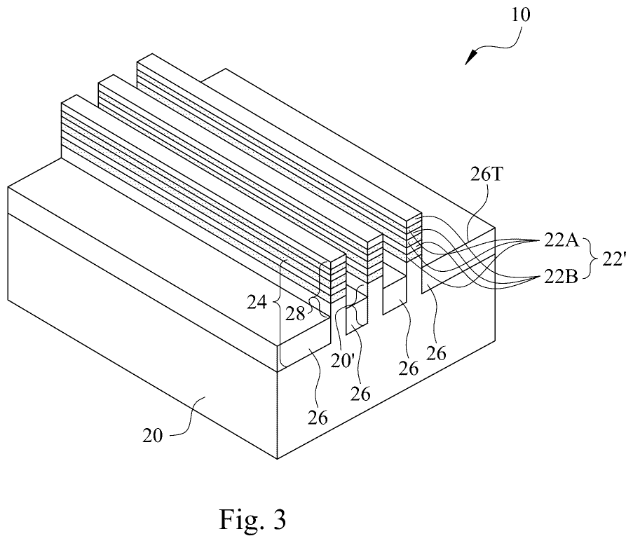

FIG. 3 illustrates the formation of isolation regions 26, which are also referred to as Shallow Trench Isolation (STI) regions throughout the description. The respective process is illustrated as process 206 in the process flow 200 shown as in FIG. 34. STI regions 26 may include a liner oxide (not shown), which may be a thermal oxide formed through the thermal oxidation of a surface layer of substrate 20. The liner oxide may also be a deposited silicon oxide layer formed using, for example, ALD, High-Density Plasma Chemical Vapor Deposition (HDPCVD), CVD, or the like. STI regions 26 may also include a dielectric material over the liner oxide, wherein the dielectric material may be formed using Flowable Chemical Vapor Deposition (FCVD), spin-on coating, HDPCVD, or the like. A planarization process such as a Chemical Mechanical Polish (CMP) process or a mechanical grinding process may then be performed to level the top surface of the dielectric material, and the remaining portions of the dielectric material are STI regions 26.

STI regions 26 are then recessed, so that the top portions of semiconductor strips 24 protrude higher than the top surfaces 26T of the remaining portions of STI regions 26 to form protruding fins 28. Protruding fins 28 include multilayer stacks 22′ and the top portions of substrate strips 20′. The recessing of STI regions 26 may be performed through a dry etching process, wherein NF₃ and NH₃, for example, are used as the etching gases. During the etching process, plasma may be generated. Argon may also be included. In accordance with alternative embodiments of the present disclosure, the recessing of STI regions 26 is performed through a wet etching process. The etching chemical may include HF, for example.

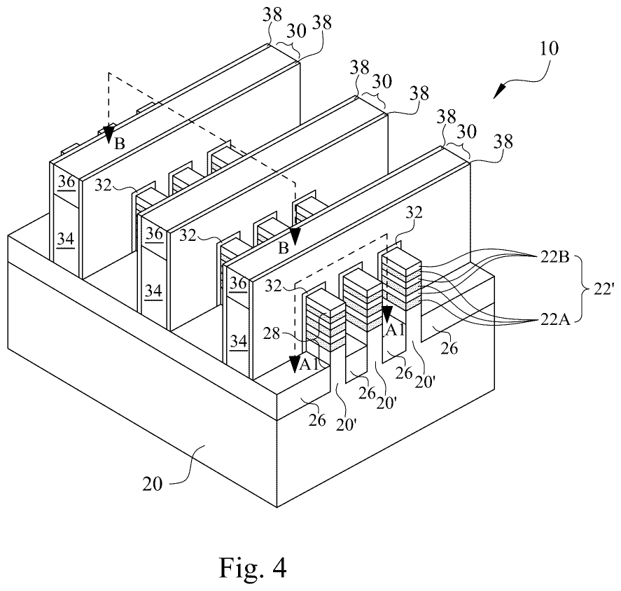

Referring to FIG. 4, dummy gate stacks 30 and gate spacers 38 are formed on the top surfaces and the sidewalls of (protruding) fins 28. The respective process is illustrated as process 208 in the process flow 200 shown as in FIG. 34. Dummy gate stacks 30 may include dummy gate dielectrics 32 and dummy gate electrodes 34 over dummy gate dielectrics 32. Dummy gate dielectrics 32 may be formed by oxidizing the surface portions of protruding fins 28 to form oxide layers, or by depositing a dielectric layer such as a silicon oxide layer. Dummy gate electrodes 34 may be formed, for example, using polysilicon or amorphous silicon, and other materials such as amorphous carbon may also be used.

Each of dummy gate stacks 30 may also include one (or a plurality of) hard mask layer 36 over dummy gate electrode 34. Hard mask layers 36 may be formed of silicon nitride, silicon oxide, silicon carbo-nitride, silicon oxy-carbo nitride, or multilayers thereof. Dummy gate stacks 30 may cross over a single one or a plurality of protruding fins 28 and the STI regions 26 between protruding fins 28. Dummy gate stacks 30 also have lengthwise directions perpendicular to the lengthwise directions of protruding fins 28. The formation of dummy gate stacks 30 includes forming a dummy gate dielectric layer, depositing a dummy gate electrode layer over the dummy gate dielectric layer, depositing one or more hard mask layers, and then patterning the formed layers through a pattering process(es).

Next, gate spacers 38 are formed on the sidewalls of dummy gate stacks 30. In accordance with some embodiments of the present disclosure, gate spacers 38 are formed of a dielectric material such as silicon nitride (SiN), silicon oxide (SiO), silicon carbide (SiC), silicon oxide (SiO₂), silicon carbo-nitride (SiCN), silicon oxynitride (SiON), silicon oxy-carbo-nitride (SiOCN), or the like, and may have a single-layer structure or a multilayer structure including a plurality of dielectric layers. The formation process of gate spacers 38 may include depositing one or a plurality of dielectric layers, and then performing an anisotropic etching process(es) on the dielectric layer(s). The remaining portions of the dielectric layer(s) are gate spacers 38.

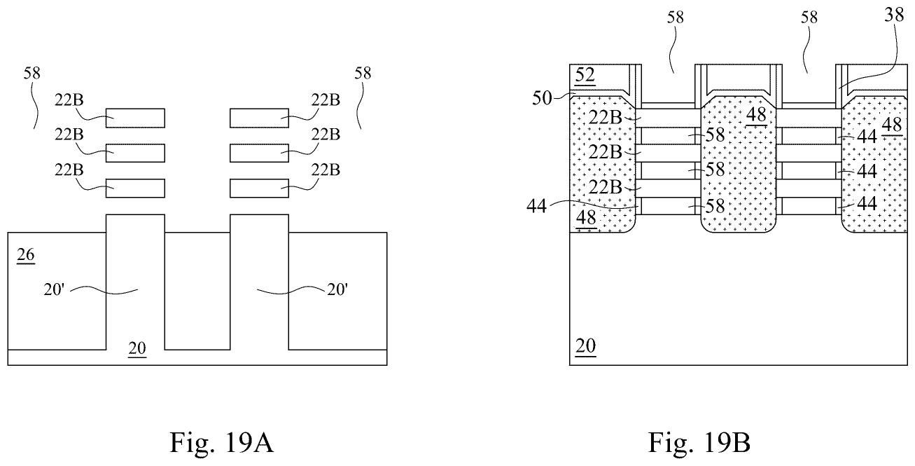

In accordance with alternative embodiments, one or more layers of gate spacers 38 may be formed using the processes as illustrated in FIG. 19, and the resulting layer of gate spacers 38 comprises the material as discussed referring to FIGS. 19 through 21. For example, gate spacers 38 may be formed of or include SiOCNH therein. The details of the formation processes are discussed in subsequent paragraphs.

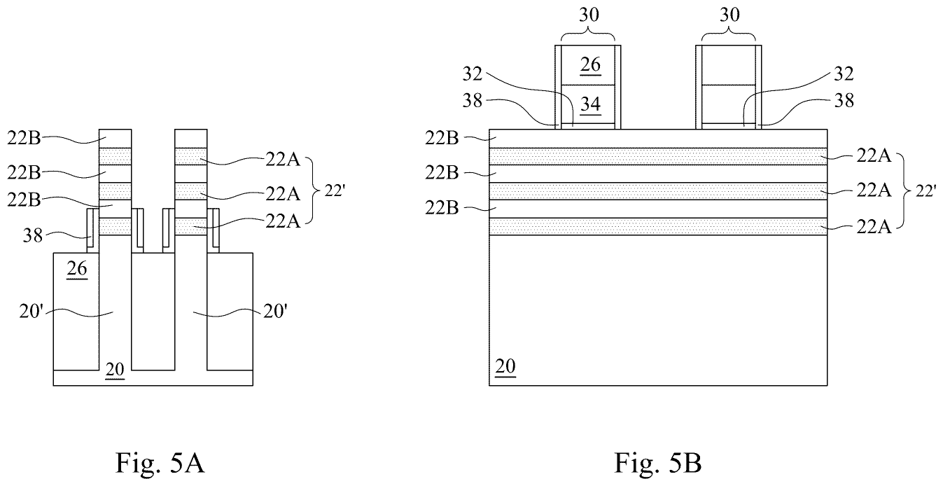

FIGS. 5A and 5B illustrate the cross-sectional views of the structure shown in FIG. 4. FIG. 5A illustrates the reference cross-section A1-A1 in FIG. 4, which cross-section cuts through the portions of protruding fins 28 not covered by gate stacks 30 and gate spacers 38, and is perpendicular to the gate-length direction. Fin spacers 38, which are on the sidewalls of protruding fins 28, are also illustrated. FIG. 5B illustrates the reference cross-section B-B in FIG. 4, which reference cross-section is parallel to the lengthwise directions of protruding fins 28.

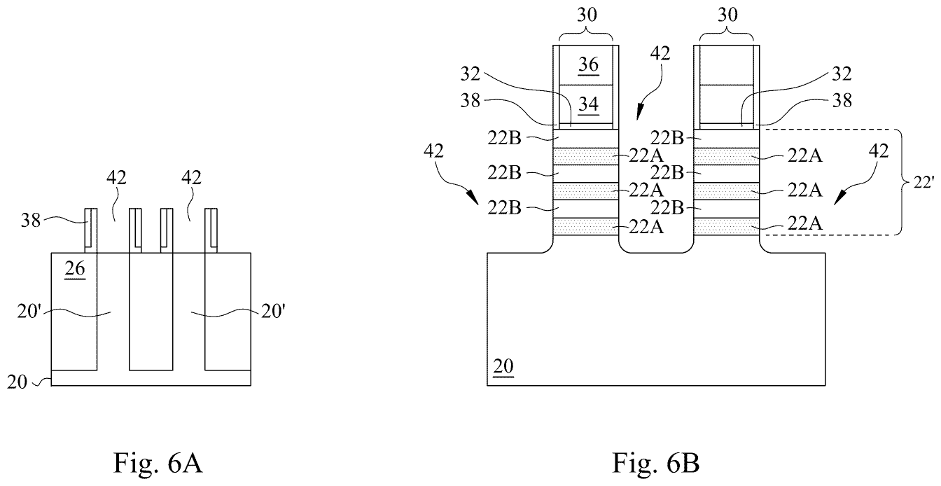

Referring to FIGS. 6A and 6B, the portions of protruding fins 28 that are not directly underlying dummy gate stacks 30 and gate spacers 38 are recessed through an etching process to form recesses 42. The respective process is illustrated as process 210 in the process flow 200 shown as in FIG. 34. For example, a dry etch process may be performed using C₂F₆, CF₄, SO₂, the mixture of HBr, Cl₂, and O₂, the mixture of HBr, Cl₂, O₂, and CH₂F₂, or the like to etch multilayer semiconductor stacks 22′ and the underlying substrate strips 20′. The bottoms of recesses 42 are at least level with, or may be lower than (as shown in FIG. 6B), the bottoms of multilayer semiconductor stacks 22′. The etching may be anisotropic, so that the sidewalls of multilayer semiconductor stacks 22′ facing recesses 42 are vertical and straight, as shown in FIG. 6B.

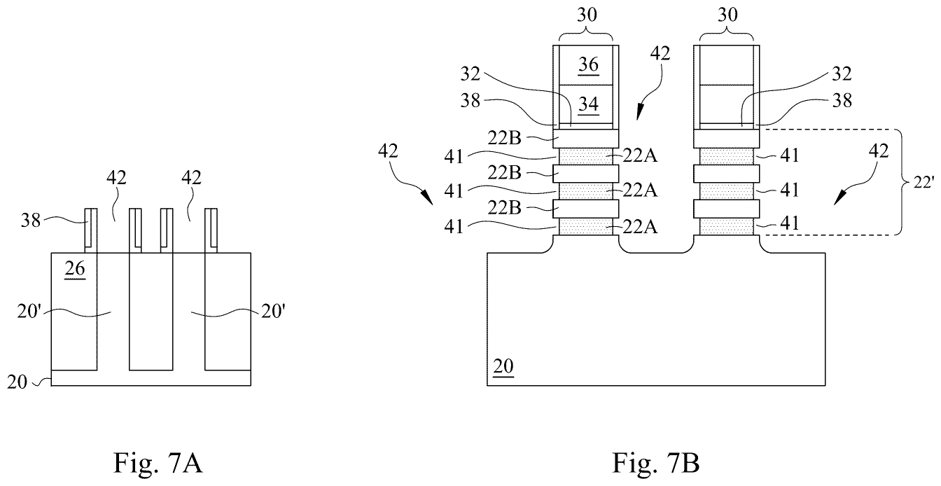

Referring to FIGS. 7A and 7B, sacrificial semiconductor layers 22A are laterally recessed to form lateral recesses 41, which are recessed from the edges of the respective overlying and underlying nanostructures 22B. The respective process is illustrated as process 212 in the process flow 200 shown as in FIG. 34. The lateral recessing of sacrificial semiconductor layers 22A may be achieved through a wet etching process using an etchant that is more selective to the material (for example, silicon germanium (SiGe) of sacrificial semiconductor layers 22A than the material (for example, silicon (Si) of the nanostructures 22B and substrate 20. For example, in an embodiment in which sacrificial semiconductor layers 22A are formed of silicon germanium and the nanostructures 22B are formed of silicon, the wet etching process may be performed using an etchant such as hydrochloric acid (HCl). The wet etching process may be performed using a dip process, a spray process, a spin-on process, or the like.

In accordance with alternative embodiments, the lateral recessing of sacrificial semiconductor layers 22A is performed through an isotropic dry etching process or a combination of a dry etching process and a wet etching process.

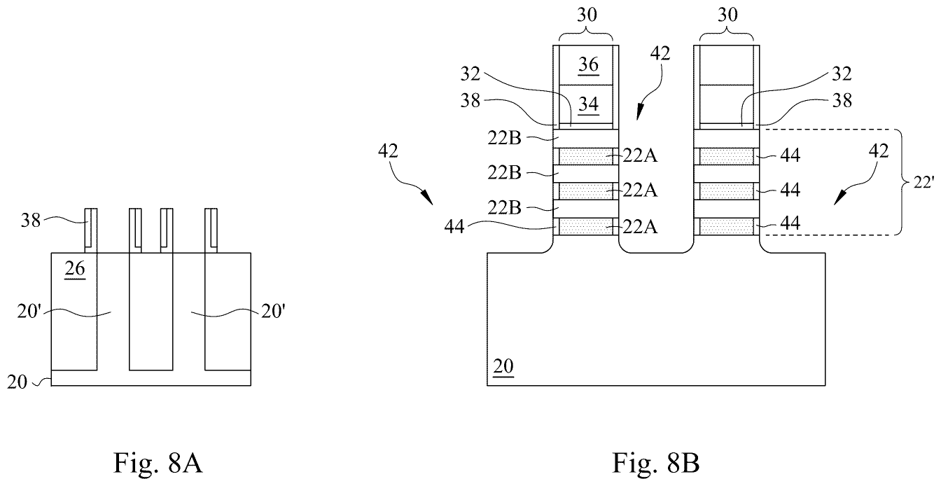

Referring to FIGS. 8A and 8B, inner spacers 44 are formed. The respective process is illustrated as process 214 in the process flow 200 shown as in FIG. 34. In accordance with some embodiments, the formation of inner spacers 44 includes depositing a conformal dielectric layer, which extends into the lateral recesses 41 (FIG. 7B). Next, an etching process (also referred to as a spacer trimming process) is performed to trim the portions of the spacer layer outside of the lateral recesses 41, leaving the portions of the spacer layer in the lateral recesses 41. The remaining portions of the spacer layer are referred to as inner spacers 44.

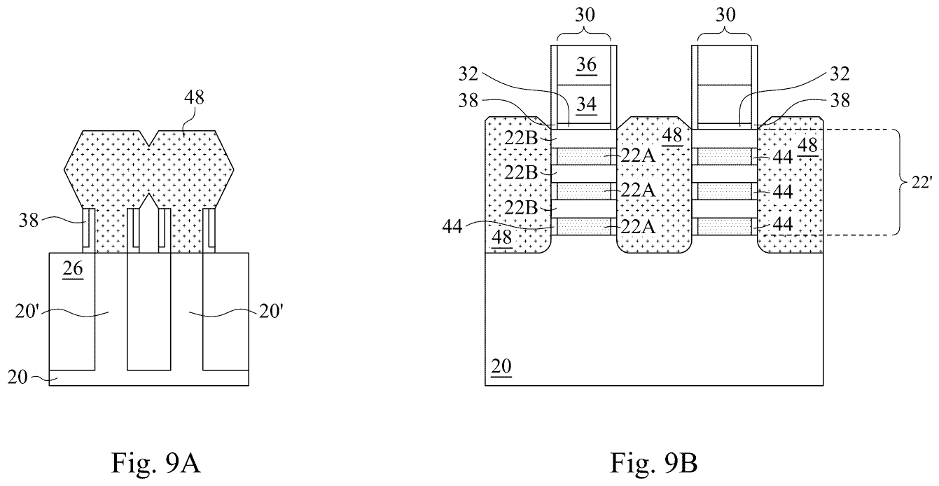

FIGS. 9A and 9B illustrate the cross-sectional views and a perspective view in the formation source/drain regions 48 in recesses 42 through epitaxy. The respective process is illustrated as process 216 in the process flow 200 shown as in FIG. 34. Source/drain region(s) may refer to a source or a drain, individually or collectively dependent upon the context. In accordance with some embodiments, the source/drain regions 48 may exert stress on the nanostructures 22B, which are used as the channels of the corresponding GAA transistors, thereby improving performance.

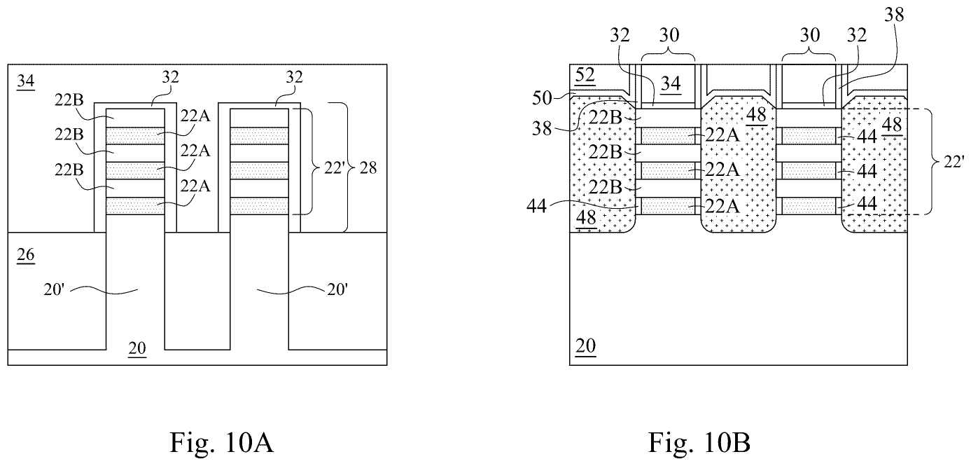

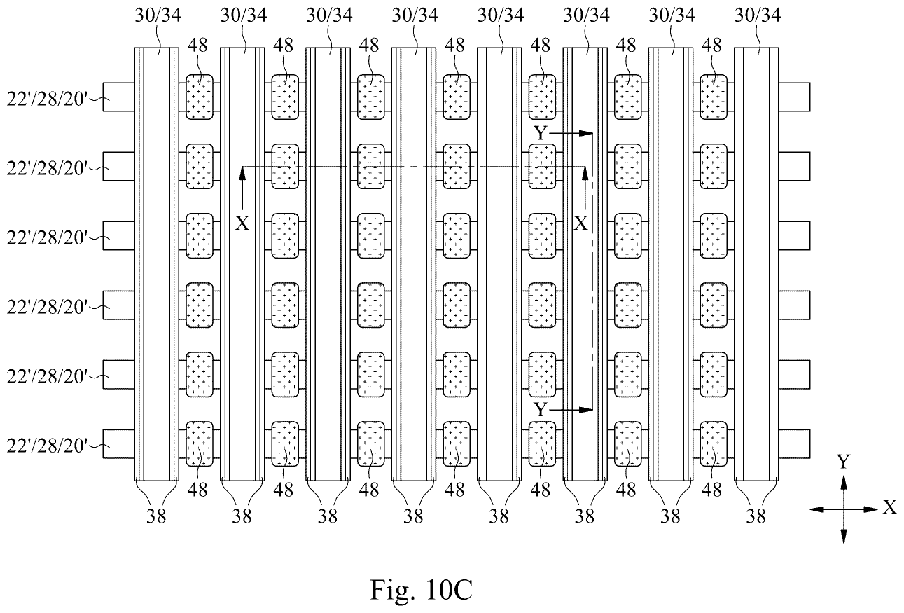

In accordance with some embodiments, the corresponding transistor is n-type, and epitaxial source/drain regions 48 are accordingly formed as n-type by doping an n-type dopant. For example, silicon phosphorous (SiP), silicon carbon phosphorous (SiCP), or the like may be grown to form epitaxial source/drain regions 48. In accordance with alternative embodiments, the corresponding transistor is p-type, and epitaxial source/drain regions 48 are accordingly formed as p-type by doping a p-type dopant. For example, silicon boron (SiB), silicon germanium boron (SiGeB), or the like may be grown to form epitaxial source/drain regions 48. After recesses 42 are filled with epitaxy regions 48, the further epitaxial growth of epitaxy regions 48 causes epitaxy regions 48 to expand horizontally, and facets may be formed. The further growth of epitaxy regions 48 may also cause neighboring epitaxy regions 48 to merge with each other, with voids 49 (FIG. 10C) being formed.

After the epitaxy process, epitaxy regions 48 may be further implanted with an n-type impurity or a p-type impurity to form source and drain regions, which are also denoted using reference numeral 48. In accordance with alternative embodiments of the present disclosure, the implantation process is skipped when epitaxy regions 48 are in-situ doped with the n-type impurity or p-type impurity during the epitaxy, and the epitaxy regions 48 are also source/drain regions.

FIGS. 10A and 10B illustrate the cross-sectional views of the structure after the formation of Contact Etch Stop Layer (CESL) 50 and Inter-Layer Dielectric (ILD) 52. The respective process is illustrated as process 218 in the process flow 200 shown as in FIG. 34. CESL 50 may be formed of silicon oxide, silicon nitride, silicon carbo-nitride, or the like, and may be formed using CVD, ALD, or the like. ILD 52 may include a dielectric material formed using, for example, FCVD, spin-on coating, CVD, or any other suitable deposition method. ILD 52 may be formed of an oxygen-containing dielectric material, which may be a silicon-oxide based material formed using Tetra Ethyl Ortho Silicate (TEOS) as a precursor, Phospho-Silicate Glass (PSG), Boro-Silicate Glass (BSG), Boron-Doped Phospho-Silicate Glass (BPSG), Undoped Silicate Glass (USG), or the like.

CESL 50 and ILD 52 are planarized through a planarization process such as a CMP process or a mechanical grinding process. In accordance with some embodiments, the planarization process may remove hard masks 36 to reveal dummy gate electrodes 34, as shown in FIG. 10A. In accordance with alternative embodiments, the planarization process may reveal, and is stopped on, hard masks 36. In accordance with some embodiments, after the planarization process, the top surfaces of dummy gate electrodes 34 (or hard masks 36), gate spacers 38, and ILD 52 are level within process variations.

FIG. 10C illustrates a top view of the structure shown in FIGS. 10A and 10B in accordance with some embodiments. Multilayer stacks 22′, substrate strips 20′, and protruding fins 28 (refer to FIG. 10A) have lengthwise directions in the X-direction, and the corresponding cross-sectional view is referred to as the X-cut view. Gate stacks 30, which includes dummy gate electrodes 34 (such as polysilicon strips) have lengthwise directions in the Y-direction, and the corresponding cross-sectional view is referred to as the Y-cut view. Source/drain regions 48 are formed based on some portions of the multilayer stacks 22′ (as viewed in FIGS. 5B and 10B). The edges of source/drain regions may be in contact with, or may be spaced apart from, gate spacers 38.

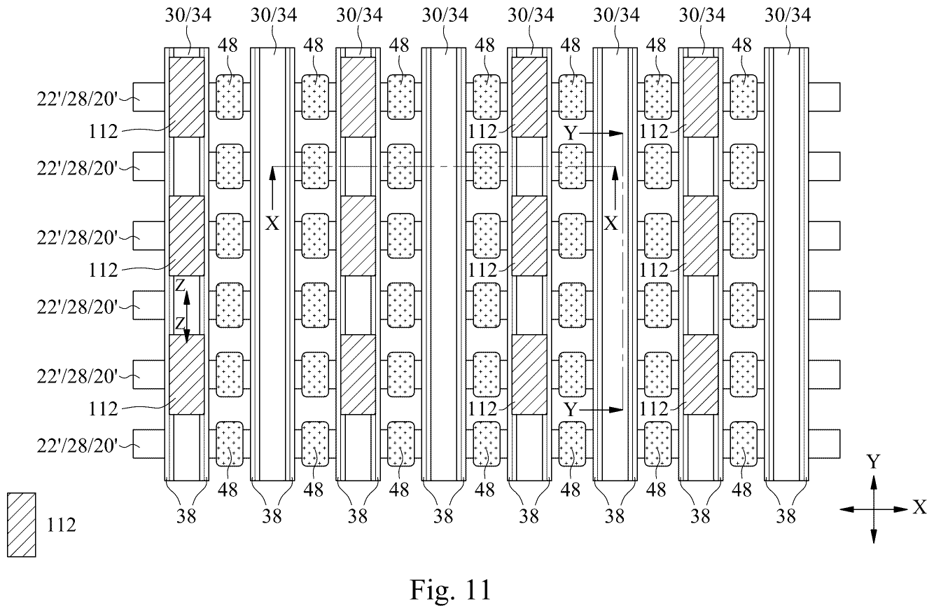

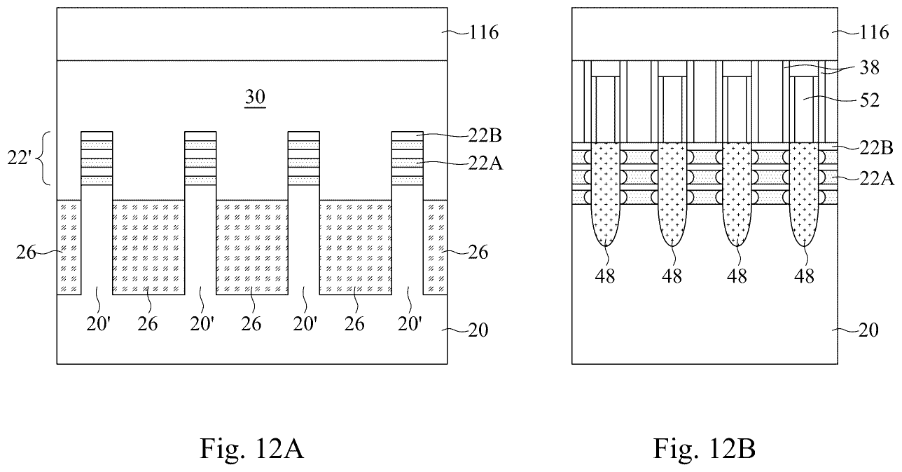

FIG. 11 illustrates the top view of the formation of fin isolation regions 112. In accordance with some embodiments, as shown in FIG. 11, fin isolation regions 112 are Continuous Polysilicon on Diffusion edge (CPODE) regions, whose formation involves etching dummy gate stacks 30, multilayer stacks 22′, and substrate strips 20′. The respective process is also illustrated as process 220 in the process flow 200 shown as in FIG. 34. The detailed process for forming fin isolation regions 112 by cutting dummy gate stacks 30 are shown in FIGS. 12A through 18B.

FIGS. 12A and 12B through 18A and 18B illustrate the formation of fin isolation regions 112 (using CPODE processes) in accordance with some embodiments. In subsequent figures, the figures having letter A following the corresponding figure numbers are obtained from the Y-cut (along Y-direction) in FIG. 11, while the figures having letter B following the corresponding figure numbers are obtained from the X-cut (along X-direction) in FIG. 11.

FIGS. 12A and 12B illustrate the structure in FIG. 10C, and are obtained from the cross-sections Y-cut and X-Cut, respectively. FIGS. 12A and 12B also correspond to FIGS. 10A and 10B, respectively. Accordingly, FIG. 12A illustrates multi-layer stacks 22′, and dummy gate stack 30 on multi-layer stacks 22′. FIG. 12B illustrates source/drain regions 48, multi-layer stacks 22′, inner spacers 44, and dummy gate stacks 30.

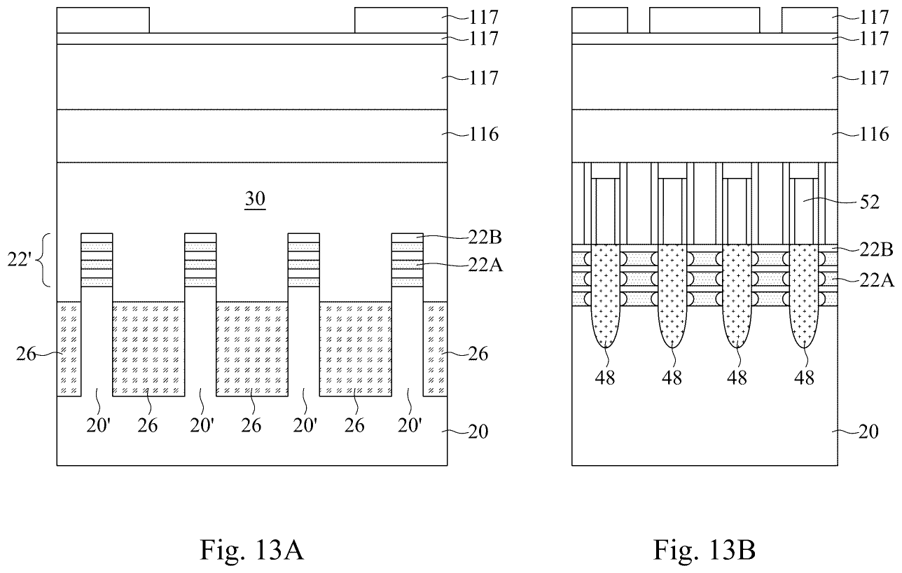

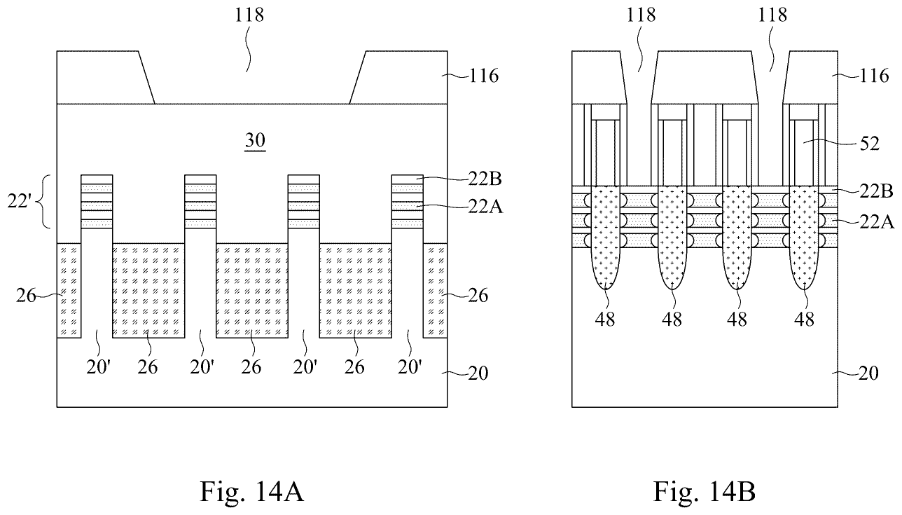

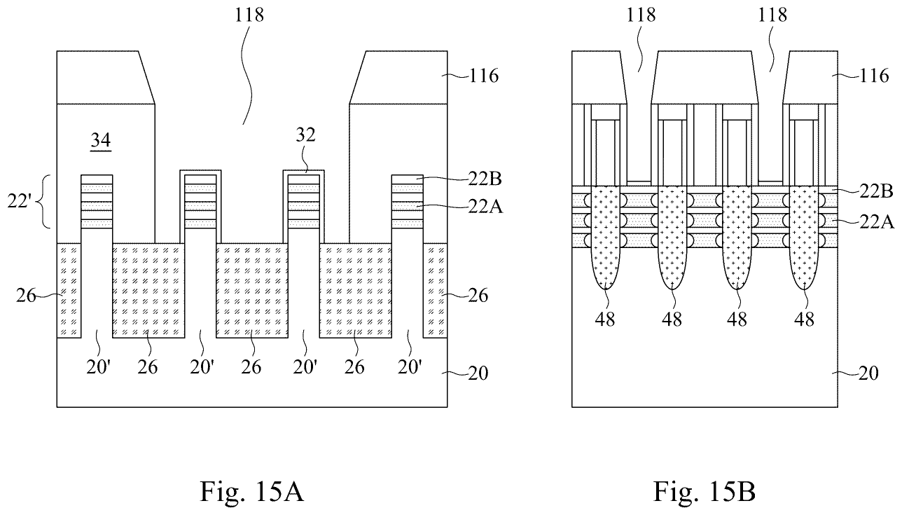

Referring to FIGS. 12A and 12B, hard mask 116 is formed. Hard mask 116 may comprise a dielectric material such as SiN, silicon, or the like, or multi-layers thereof. Etching mask 117 (e.g., a tri-layer photoresist), which is patterned, is formed over hard mask 116. Next, as shown in FIGS. 13A-14B, hard mask 116 is etched to form openings 118, through which dummy gate electrode of the dummy gate stacks 30 is exposed. Hard mask 116 is then used to etch-through the underlying dummy gate electrode, until the dummy gate dielectric of the dummy gate stacks 30 is exposed, as shown in FIGS. 15A and 15B. The etching is anisotropic, so that the edges of the dummy gate electrode facing opening 118 are vertical and straight. In the etching process, dummy gate dielectric may be used as an etch stop layer.

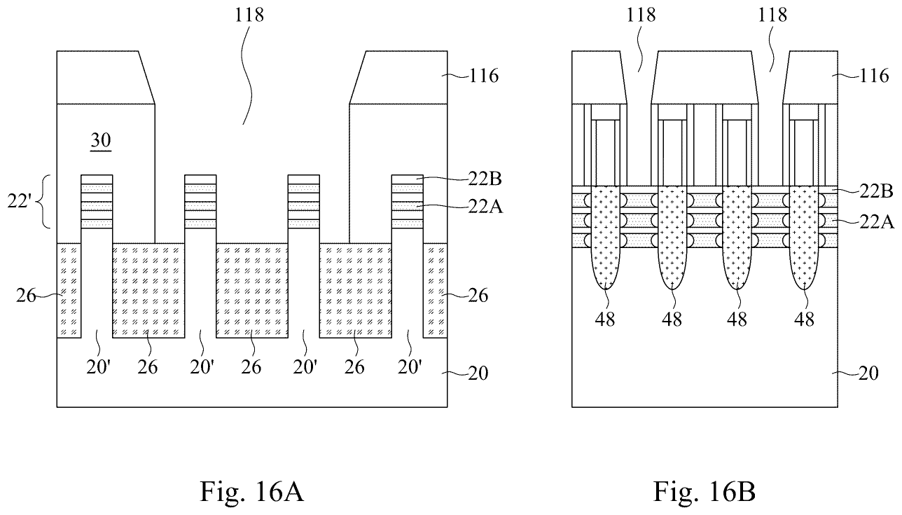

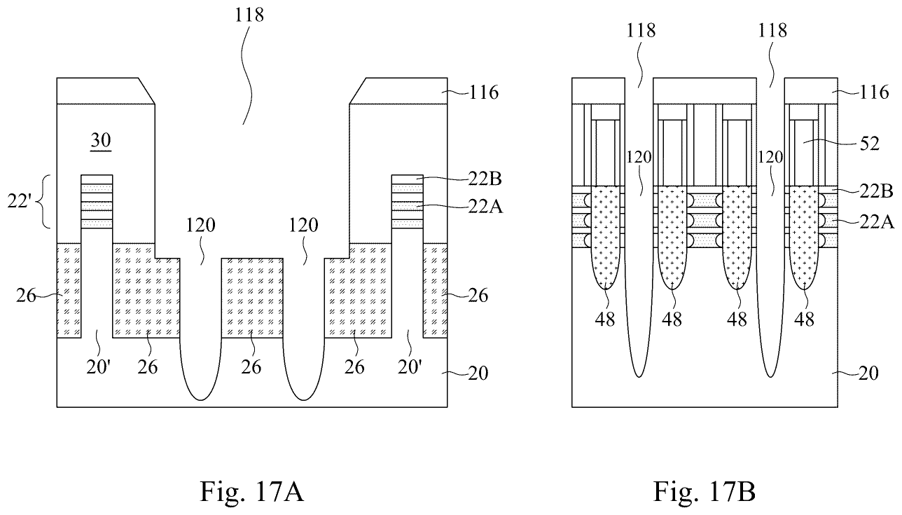

The dummy gate dielectric of the dummy gate stacks is then removed, for example, through an isotropic etching process, so that multi-layer stacks 22′ are revealed. The resulting structure is shown in FIGS. 16A and 16B. Next, an etching process(es) is performed to remove the exposed multi-layer stacks 22′, followed by the further etching of the underlying semiconductor material such as semiconductor strips 20′. Openings 120 are thus formed between neighboring STI regions 26, as shown in FIGS. 17A and 17B. Openings 120 may extend to a level lower than the bottom surfaces of STI regions 26 to reduce leakage.

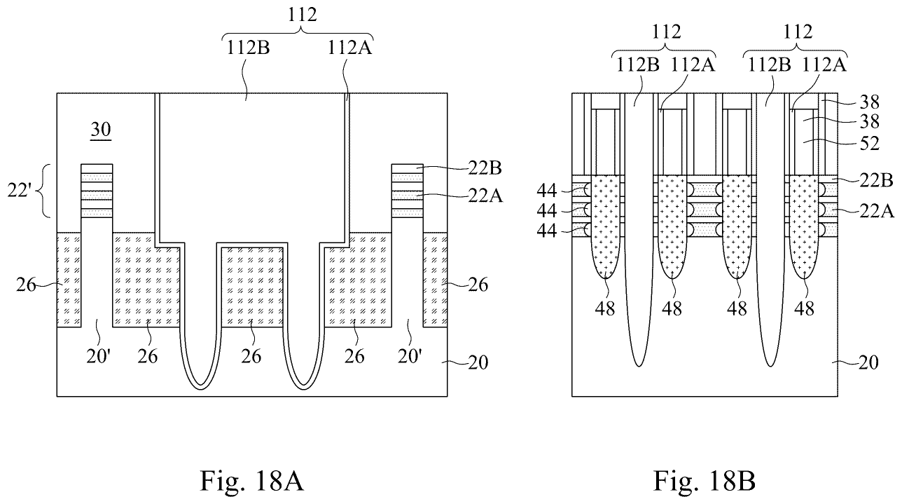

FIGS. 18A and 18B illustrate the filling of openings 118 and 120 to form CPODE isolation region 112. In accordance with some embodiments, the filling process may include depositing a dielectric liner 112A, followed by depositing a dielectric layer 112B on dielectric liner 112A. In accordance with some embodiments, the materials of dielectric liner 112A and dielectric layer 112B may be selected from SiN, SiO, SiON, SiOCN, SiCN, or the like, or combinations thereof. A planarization process such as a CMP process may then be performed to form fin isolation region 112, which is a CPODE isolation region, which is also shown in FIG. 11.

Next, the dummy gate electrodes and the dummy gate dielectrics of the dummy gate stacks 30 (and hard masks 36, if remaining) are removed in one or more etching processes, so that recesses 58 are formed, as shown in FIGS. 19A and 19B. The respective process is illustrated as process 222 in the process flow 200 shown as in FIG. 34. In accordance with some embodiments, dummy gate electrodes and dummy gate dielectrics are removed through an anisotropic dry etch process(es). For example, the etching process may be performed using reaction gas(es) that selectively etch dummy gate electrodes and dummy gate dielectrics at faster rates than ILD 52. Each recess 58 exposes and/or overlies portions of multilayer stacks 22′, which include the future channel regions in subsequently completed transistors.

Sacrificial layers 22A are then removed to extend recesses 58 between nanostructures 22B. The respective process is illustrated as process 224 in the process flow 200 shown as in FIG. 34. Sacrificial layers 22A may be removed by performing an isotropic etching process such as a wet etching process using etchants which are selective to the materials of sacrificial layers 22A, while nanostructures 22B, substrate 20, and STI regions 26 remain relatively un-etched as compared to sacrificial layers 22A. In accordance with some embodiments in which sacrificial layers 22A include, for example, SiGe, and nanostructures 22B include, for example, Si or SiC, tetra methyl ammonium hydroxide (TMAH), ammonium hydroxide (NH4OH), or the like may be used to remove sacrificial layers 22A.

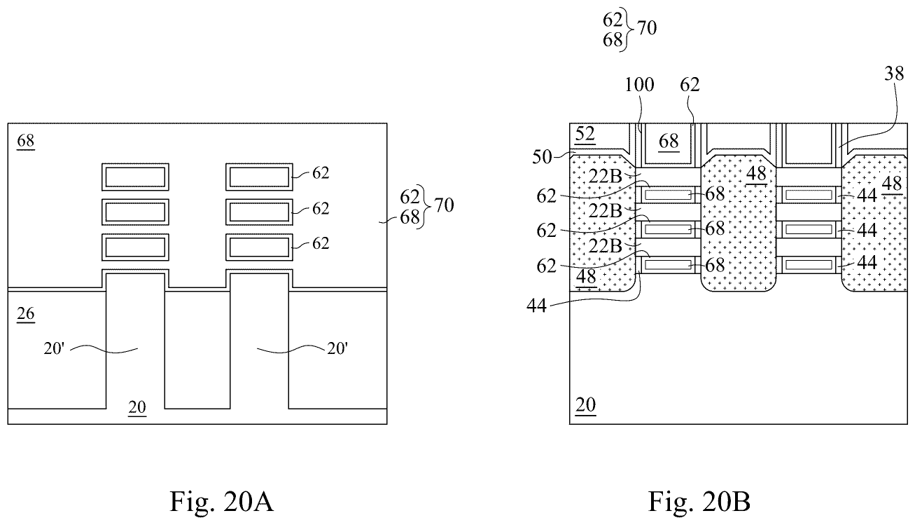

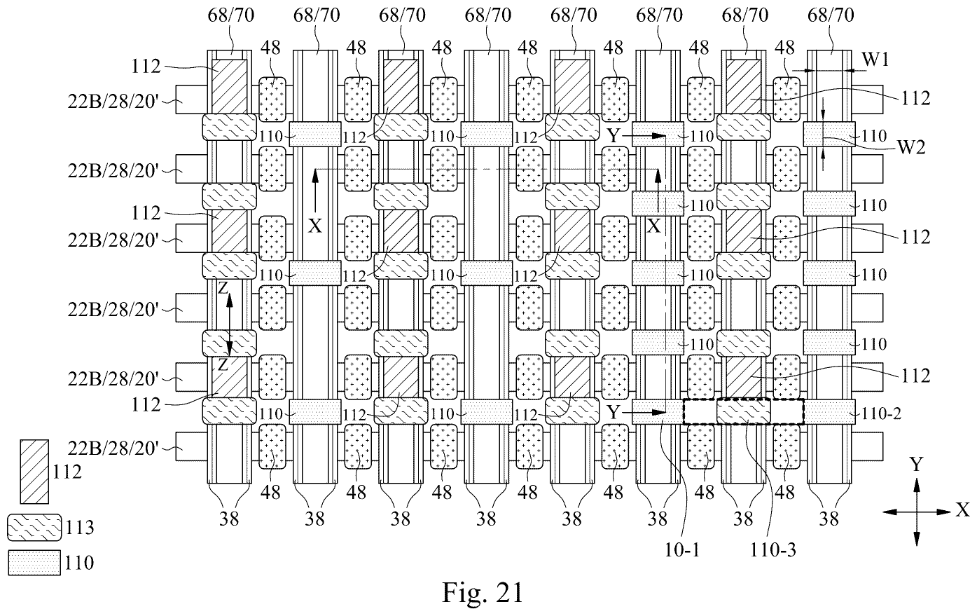

Referring to FIGS. 20A and 20B, gate dielectrics 62 and gate electrodes 68 are formed, hence forming replacement gate stacks 70. The respective process is illustrated as process 226 in the process flow 200 shown as in FIG. 34. In accordance with some embodiments, each of gate dielectric 62 includes an interfacial layer and a high-k dielectric layer on the interfacial layer. The interfacial layer may be formed of or comprises silicon oxide, which may be deposited through a conformal deposition process such as ALD or CVD, or through an oxidation process. In accordance with some embodiments, the high-k dielectric layers comprise one or more dielectric layers. For example, the high-k dielectric layer(s) may include a metal oxide or a silicate of hafnium, aluminum, zirconium, lanthanum, manganese, barium, titanium, lead, and combinations thereof.

Gate electrodes 68 are also formed. In the formation, conductive layers are first formed on the high-k dielectric layer, and the remaining portions of recesses 58 are filled. Gate electrodes 68 may include a metal-containing material such as TiN, TaN, TiAl, TiAlC, cobalt, ruthenium, aluminum, tungsten, combinations thereof, and/or multilayers thereof. For example, gate electrodes 68 may comprise any number of layers, any number of work function layers, and possibly a filling material. Gate dielectrics 62 and gate electrodes 68 also fill the spaces between adjacent ones of nanostructures 22B, and fill the spaces between the bottom ones of nanostructures 22B and the underlying substrate strips 20′. After the filling of recesses 58, a planarization process such as a CMP process or a mechanical grinding process is performed to remove the excess portions of the gate dielectrics and the material of gate electrodes 68, which excess portions are over the top surface of ILD 52. Gate electrodes 68 and gate dielectrics 62 are collectively referred to as gate stacks 70 of the resulting transistors.

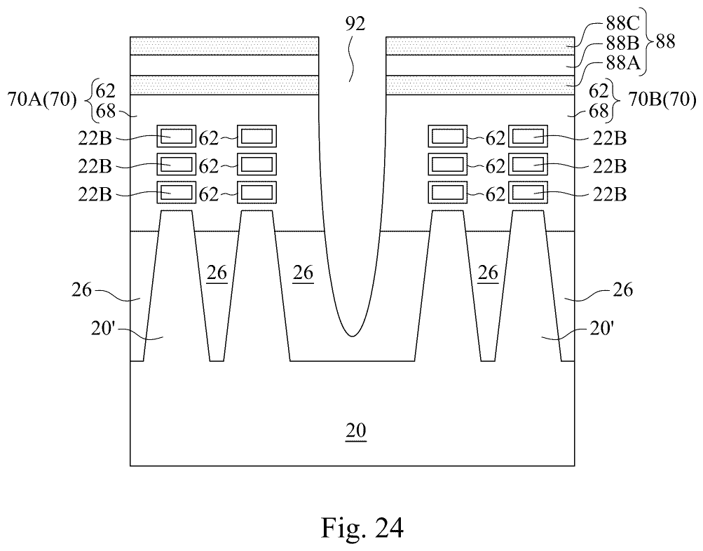

Following the formation of the gate stacks 70, Cut-Metal Gate (CMG) regions 110 may be formed, as depicted in FIGS. 21-26. FIG. 21 illustrates the top view of the formation of Cut-Metal Gate (CMG) regions 110, whose formation separates/divides the replacement (metal) gate stacks 70 into shorter portions. The respective process is illustrated as process 228 in the process flow 200 shown as in FIG. 34. CMG isolation regions 110 are also referred to as gate isolation regions 110. In accordance with some embodiments, the CMG isolation regions 110 are formed by cutting replacement gate stacks 70, as shown in FIG. 24.

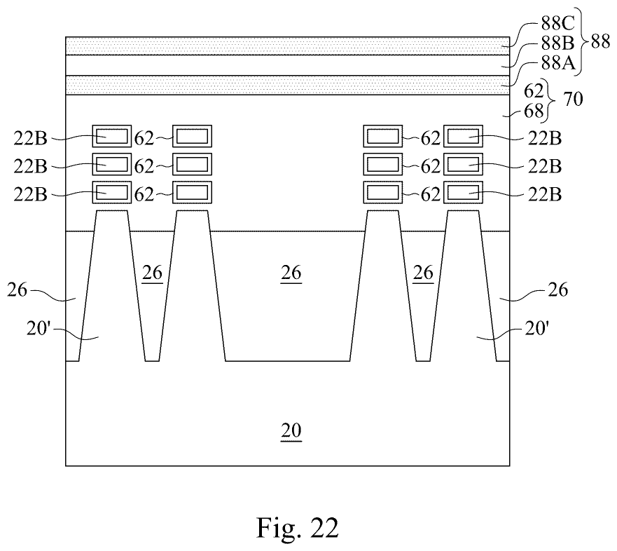

The detailed process for forming CMG isolation regions 110 may be realized from the processes shown in FIGS. 22-26. FIG. 22 illustrates a cross-sectional view of an intermediate structure, in which gate stack 70 has been formed, and includes gate dielectrics 62 and gate electrode 68, while CMG isolation region 110 has not been formed yet. In accordance with some embodiments, hard mask layer 88 is deposited, and may include a multi-layer structure including a plurality of layers. In accordance with some embodiments, hard mask layers 88 include silicon nitride layer 88A, silicon layer 88B, and silicon nitride layer 88C. In accordance with alternative embodiments, a single-layer hard mask 88 is used, which may be formed of or comprise silicon nitride.

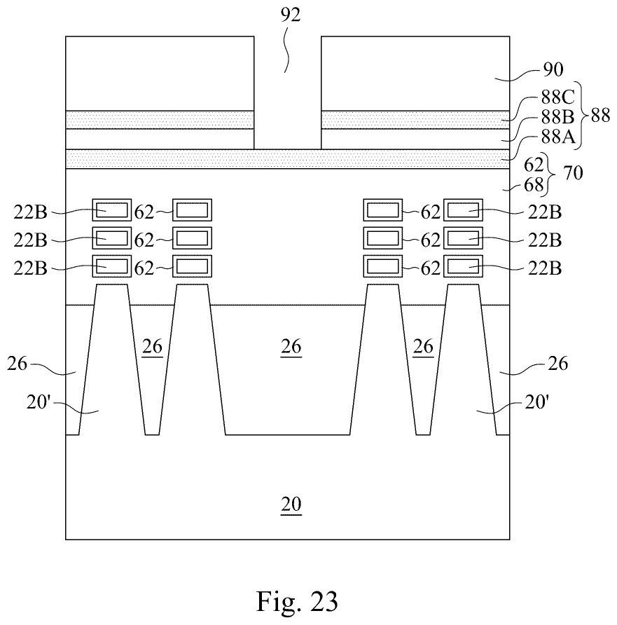

Etching mask 90 is then formed, as shown in FIG. 23. Etching mask 90 may also have a single-layer structure (which may include a photoresist) or a dual-layer structure including a Bottom Anti-reflective Coating (BARC) and a photoresist. Alternatively, etching mask 90 may have a tri-layer, which may include a bottom layer, a middle layer over the bottom layer, and a top layer, which may be a patterned photoresist. Trench 92 is formed in etching mask 90.

Next, etching mask 90 is used to etch mask layers 88, so that trench 92 extends into hard mask layers 88. The etching may be anisotropic. In accordance with some embodiments, trench 92 extends to the top surface of hard mask 88A. Etching mask 90 may be removed after trench 92 is formed in hard mask layers 88.

Next, as also shown in FIG. 24, replacement gate stack 70 is etched. The etching of replacement gate stack 70 is anisotropic. In accordance with some embodiments, the etching is performed until STI region 26 is exposed. Trench 92 may or may not extend into STI region 26. After the etching process, hard mask layers 88 may (or may not) be removed. Gate stack 70 is thus separated into gate stacks 70A and 70B.

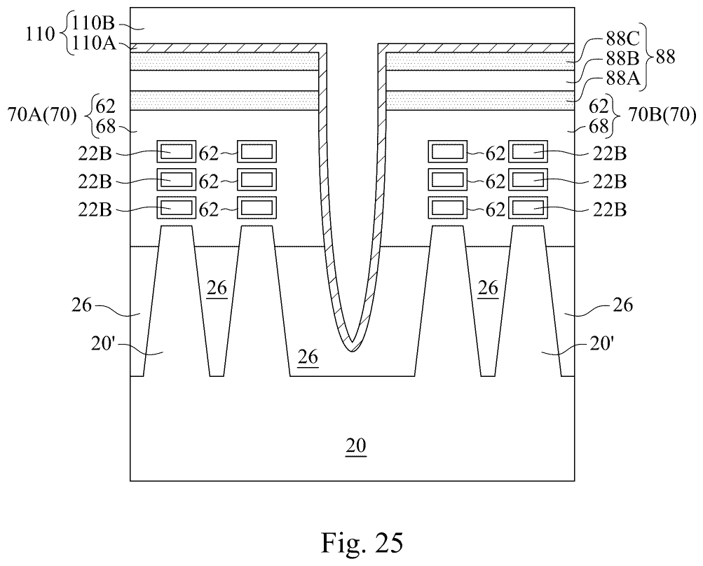

In a subsequent process, dielectric layer 110 is deposited, as shown in FIG. 25. Dielectric layer 110 may have a multi-layer structure (including dielectric layer 110A and dielectric layer 110B, for example) or may have a single-layer structure. Dielectric layer 110 and the sub layers therein may include SiO, SiN, SiCON, SiCN, SiON, SiCO, or the like.

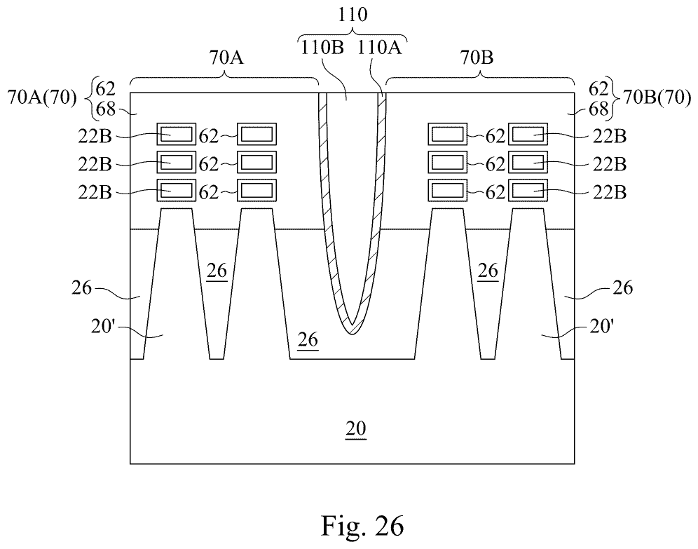

After the deposition of dielectric layer 110, a planarization process such as a CMP process or a mechanical grinding process is performed. The planarization process may be stopped on the top surfaces of gate stacks 70. The remaining portions of dielectric layers 110A and 110B are collectively referred to as CMG isolation region 110 hereinafter, as shown in FIG. 26.

Due to the separation of the CMG isolation regions 110 from fin isolation regions 112, there may be some regions separating the CMG isolation regions 110 from their neighboring fin isolation regions 112. The lengths of CMG isolation regions 110 may be selected depending on the layout of the circuit. In accordance with some embodiments, in the formation of some CMG isolation regions 110, the gate spacers 38 on opposite sides of the respective gate stacks 70 (or dummy gate stacks 30) are also etched, and hence CMG isolation regions 110 laterally extend (in the X-direction) beyond spacers 38. In accordance with alternative embodiments, some or all of CMG isolation regions 110 are limited by the opposing gate spacers 38. Some of CMG isolation regions 110 may cut into gate spacers 38, and may extend laterally beyond gate spacers 38 into the neighboring ILD regions. The lengths of CMG isolation regions 110 may also extend longer than illustrated.

FIG. 21 further illustrates the top view of the formation of Cut-Metal Gate (CMG) cut Continuous Polysilicon on Diffusion edge (CPODE) regions 113.

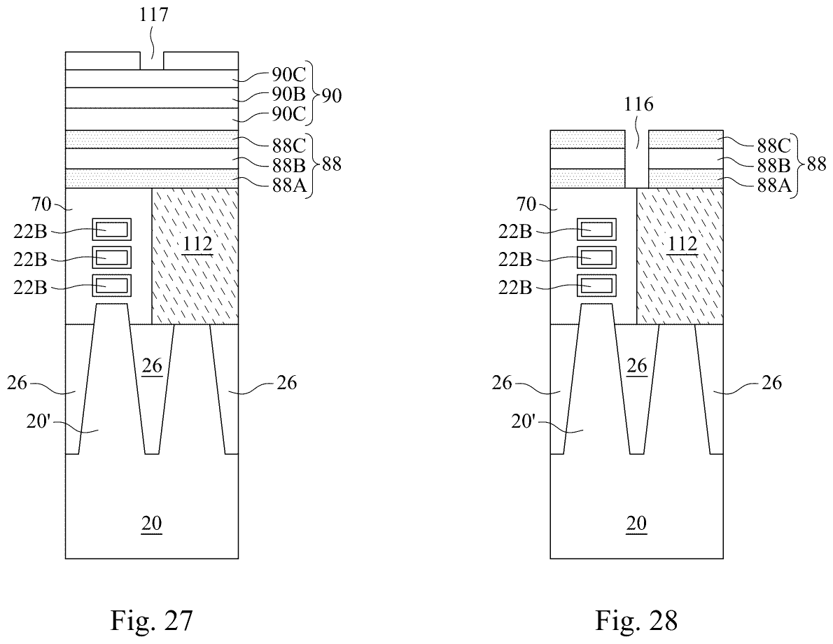

The CMG cut CPODE regions 113 may also be referred to as a CMG isolation interface 113 (also referred to as isolation interface region) between the gate structure 70 and the fin isolation region 112. The respective process is illustrated as process 228 in the process flow 200 shown as in FIG. 34. In accordance with some embodiments, the CMG isolation regions 110 are formed by cutting the interface between the replacement gate stacks 70 and the fin isolation regions 112, as shown in FIG. 21 and FIGS. 27-31. FIGS. 27-31 are side cross-sectional view taken from second line Z-Z in FIGS. 11 and 21. Although FIG. 21 illustrates a single CMG isolation interface 113 corresponding to a single interface between the gate structure 70 and the fin isolation region 112, the methods and structures described herein are not limited to only this example. For example, a single CMG isolation interface 113 may extend across multiple gate structures and multiple fin isolation regions 112 at their interfaces. For example, a single CMG isolation region 110 may extend across up to 100 gate structures and up to 100 fin isolation regions 112 at their interfaces.

In some embodiments, the CMG isolation interface 113 are formed the ends of the Continuous Polysilicon on Diffusion edge (CPODE) isolation regions 112 (also referred to as fin isolation regions 112). In some embodiments, by positioning the CMG isolation interface 113 at the ends of the Continuous Polysilicon on Diffusion edge (CPODE) isolation regions (also referred to as fin isolation regions 112), the methods and structures that are described herein can lessen or remove device leakage across the ends of the Continuous Polysilicon on Diffusion edge (CPODE) isolation regions (also referred to as fin isolation regions 112). More particularly, device leakage pathways can form across the ends of the fin isolation regions 112 during the metal fill processes that are used to form the replacement gate stacks 70. These device leakage pathways can extend to the contacts for the source/drain regions, which can result in device leakage (e.g., gate contact to gate contact leakage (MD to MD device leakage) and/or gate contact to metal gate leakage (MD to MG device leakage). The leakage pathways between the contacts to source and drain regions (MD to MD device leakage pathways) that can be present at the ends of the Continuous Polysilicon on Diffusion edge (CPODE) isolation regions (also referred to as fin isolation regions 112) abutting the metal gate (gate structure 70) can be removed using an etch step, e.g., cut metal gate (CMG) etch. In some embodiments, the leakage pathways can be removed with a cut metal gate (CMG) dry etching process that removes the leakage pathway, and can trim the profile of the edge of the CPODE regions from having a rounded profile to a square profile. In some embodiments, the cut metal gate (CMG) etch process that forms the CMG isolation interface 113 may be the same etch process that forms the CMG isolation region 110. In some embodiments, the cut metal gate (CMG) etch process that forms the CMG isolation interface 113 may be a separately performed etch process from the etch process that forms the CMG isolation region 110.

FIG. 27 illustrates a cross-sectional view of an intermediate structure, in which gate stack 70 has been formed, and includes gate dielectrics and gate electrode, while CMG isolation interface 113 has not been formed yet. In accordance with some embodiments, hard mask layer 88 is deposited, and may include a multi-layer structure including a plurality of layers. In accordance with some embodiments, hard mask layers 88 include silicon nitride layer 88A, silicon layer 88B, and silicon nitride layer 88C. In accordance with alternative embodiments, a single-layer hard mask 88 is used, which may be formed of or comprise silicon nitride.

Etching mask 90 is then formed, as shown in FIG. 27. Etching mask 90 may also have a single-layer structure (which may include a photoresist) or a dual-layer structure including a Bottom Anti-reflective Coating (BARC) and a photoresist. Alternatively, etching mask 90 may have a tri-layer, which may include a bottom layer 90A, a middle layer 90B over the bottom layer 90A, and a top layer 90C, which may be a patterned photoresist. Trench 117 is formed in etching mask 90. As noted, the etch process for forming the CMG isolation interface 113 may be performed simultaneously with the etch processes for forming the CMG isolation region 110. Therefore, the reference numbers for the etching masks used to form the CMG isolation interface 1113 may be the same as the reference numbers for the etching masks used for forming the CMG isolation region 110. In some embodiments, different etch masks may be used for forming the CMG isolation interface 113 and the CMG isolation region 110.

Next, etching mask 90 is used to etch mask layers 88, so that trench 117 extends into hard mask layers 88 providing a hardmask opening 116, as depicted in FIG. 28. The etching may be anisotropic. In accordance with some embodiments, trench extends through the hard mask 88A stopping on the upper surface of the interface between the gate structure 70 and the fin isolation region 112. In some embodiments, the etching mask 90 may be removed after trench 92 is formed in hard mask layers 88.

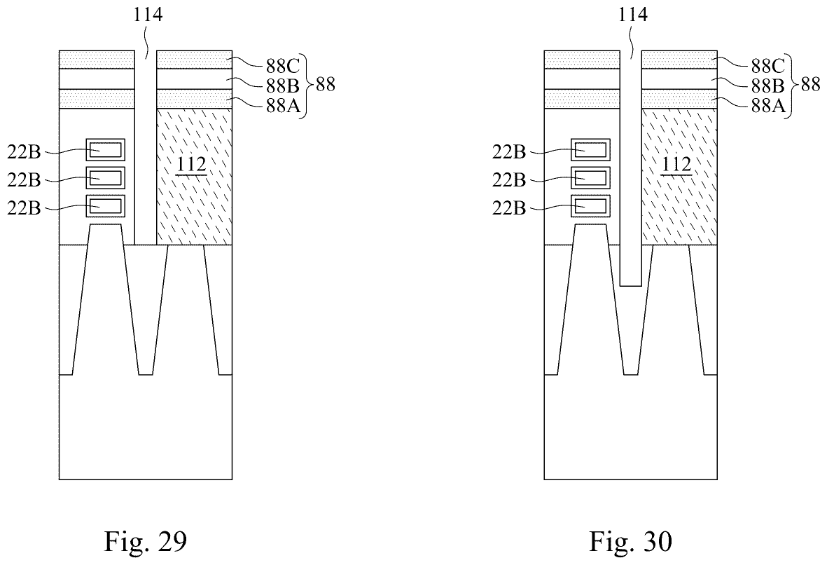

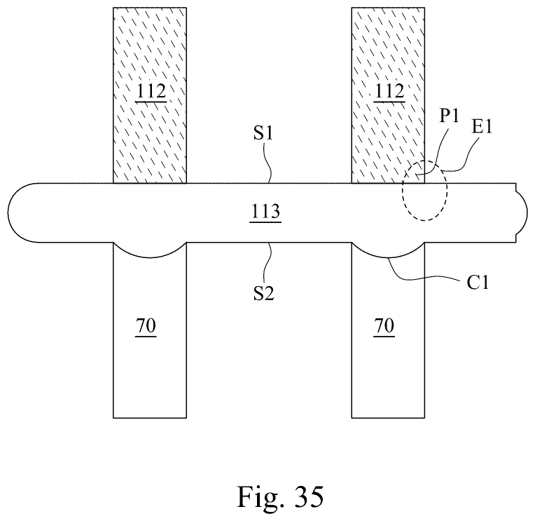

Next, as also shown in FIG. 29, the interface between the replacement gate stack 70 and the fin isolation region 110 is etched to form a trench 114 separating the end of the fin isolation region 112 from the gate structure 70. In some embodiments, etching the trench 114 at the interface of the fin isolation region 112 and the replacement gate structure 70 removes leakage paths. For example, etching the trench 114 at the interface of the fin isolation region 112 and the replacement gate structure 70 can remove voids in the fin isolation region 112 that can fill with metal from the refill processes for forming the replacement gate stack 70. By removing the metal filled voids in the fin isolation region 112 by etching the trench 114 at the interface of the fin isolation region 112 and the replacement gate structure, the methods and structures described herein can remove leakage paths that can result in device leakage, such as leakage to the contacts (MD) to the source/drain regions of the device. The etch processes applied for forming the trench 114 can also trim the end of the fin isolation region 112. For example, prior to the formation of the trench 114, the end of the fin isolation region 112 may have a curvature. The etch process that forms the trench 114 can trim the end of the fin isolation region 112, which can remove the curvature, wherein following the formation of the trench 114, the end of the fin isolation region 112 can have a profile with corners closer to being squared E1, as depicted in FIG. 35. Further, the sidewall of the fin isolation region 112 may have a planar face P1, as depicted in FIG. 35. In some embodiments, the angle for the squared edge E1 may range from 70-90.

In some embodiments, etching the trench 114 at the interface of the fin isolation region 112 and the replacement gate structure 70 can be provided by an anisotropic etch process, such as a dry etch, as depicted in FIG. 29. In some embodiments, the etch process for forming the trench 114 includes two stages. In accordance with some embodiments, the first stage of the two stage etch process is performed until STI region 26 is exposed. The trench 114 during the first stage may not extend into STI region 26. In some embodiments, the first stage of the etch process may be a dry seven (7) cycle etch that is selective to the material of the isolation regions 26, e.g., silicon oxide (SiO₂). In some embodiments, after the first stage of the etch process, a wet clean step may be performed.

In some embodiments, etching the trench 114 further includes extending the trench 114 into the isolation region 26, as depicted in FIG. 30. Extending the trench 114 into the isolation region 26 may include the second stage of the etch process. In some embodiments, the second stage of the etch process includes a five (5) cycle etch. The second stage of the etch process may include Hexafluorobutadine (Hexafluoro-1,3-butadiene)(C4F6). In some embodiments, after the second stage of the etch process, a wet clean step may be performed. After the etching process, hard mask layers 88 may (or may not) be removed.

Although, the trench 114 being formed provides that the cut portion of the fin isolation regions 112 have a planar sidewall P1 (as depicted in FIG. 35), the trench 114 forms a curved sidewall in the gate structure 70 (as depicted in FIG. 35). The difference in sidewall geometries produced in the cut portions of the fin isolation regions 112 and the gate structure 70 is the result of different etch rates for the different materials of the fin isolation regions 112 and the gate structure 70 during forming the trench 114.

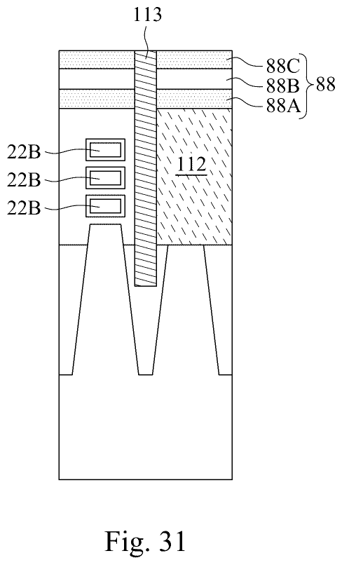

In a subsequent process, dielectric layer is deposited to provide the material for the CMG isolation interface 113, as shown in FIG. 31. In some embodiments, the dielectric layer may have a multi-layer structure or may have a single-layer structure. Dielectric layer and the sub layers therein may include SiO, SiN, SiCON, SiCN, SiON, SiCO, or the like. It is noted that the aforementioned materials have been provided for illustrative purposes and are not intended to limit the present disclosure. In some examples, the material for the CMG isolation layer 113 may include hafnium oxide (HfO), silicon oxynitride (SiNOx), zirconium dioxide (ZrO2) or other high-k dielectric materials. After the deposition of dielectric layer, a planarization process such as a CMP process or a mechanical grinding process is performed. The planarization process may be stopped on the top surfaces of gate stacks 70 and the fin isolation region 112. The remaining portions of dielectric layers provides the material for the CMG isolation interface 113, as shown in FIG. 31.

FIG. 35 is a top down view illustrating one embodiment of the an isolation interface region (also referred to as CMG isolation interface 113) between at least one of the plurality of fin isolation regions 112 and the plurality of gate structures 70, wherein the isolation interface region 113 comprises a planar face on a first sidewall S1 of the isolation interface region 113 and convex protrusions C1 extending into the plurality of gate structures 70 on a second sidewall S2 of the isolation interface region 113. As described above, the etch process that forms the trench 114 (described in FIGS. 30 and 31) for the isolation interface region 112 trims the end of the fin isolation region 112, which can remove any curvature therein. Following the formation of the trench 114, the end of the fin isolation region 112 can have a profile with corners closer to being squared E1, as depicted in FIG. 35. The dielectric fill within the trench 114 forms the isolation interface region 113, which will have a planar sidewall (e.g., the first sidewall S1) corresponding to the planar face P1 of the trench 114. The opposing sidewall (e.g., the second sidewall S2) of the dielectric fill for the isolation interface region 113 fills the convex curvature that is formed in the gate structures 70 during the etch process forming the trench 114, which results in the convex protrusions C1.

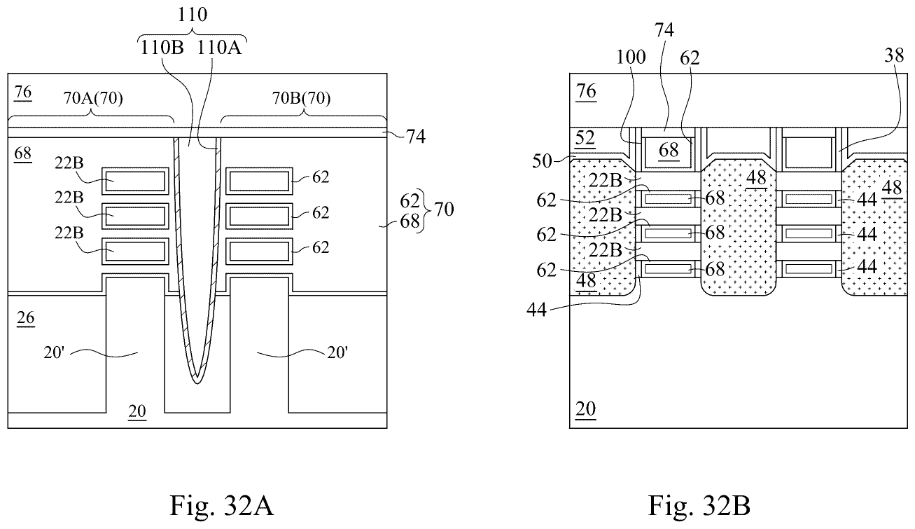

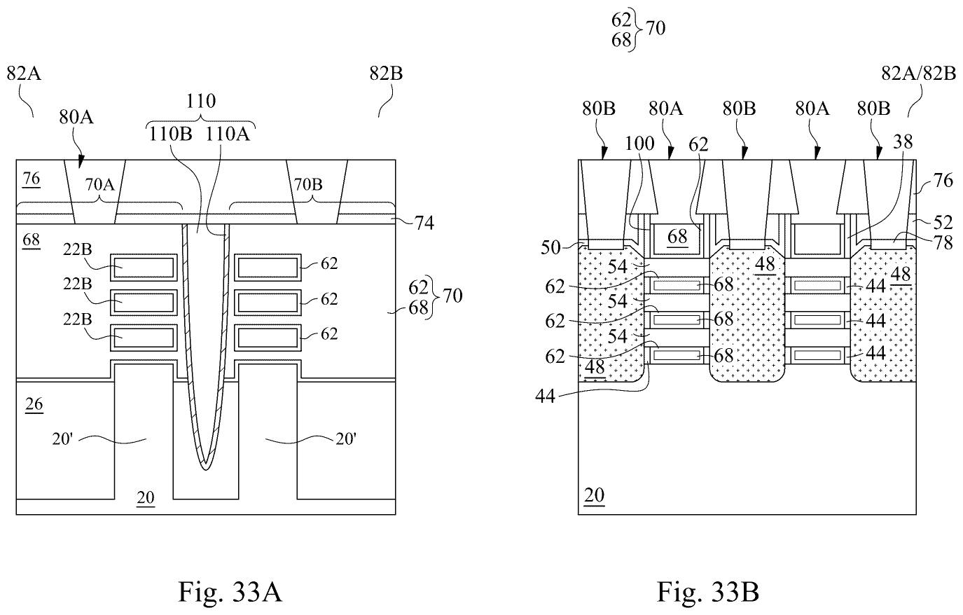

After the process as shown in FIG. 31, the remaining processes as shown in FIGS. 32A, 32B, 33A, and 33B are performed to finish the formation of the transistors 82A and 82B.

FIG. 32A illustrates a cross-sectional of the structure shown in FIG. 21, in which CMG isolation region 110 has been formed to cut long metal gate stacks 70 into metal gate stacks (portions) 70A and 70B. Next, as also shown in FIGS. 32A and 32B, gate stacks 70 are recessed, so that recesses (occupied by CMG isolation region 110) are formed directly over gate stacks 70 and between opposing portions of gate spacers 38. A gate mask 74 comprising one or more layers of dielectric material, such as silicon nitride, silicon oxynitride, or the like, is filled in each of the recesses, followed by a planarization process to remove excess portions of the dielectric material extending over ILD 52.

As further illustrated by FIGS. 32A and 32B, ILD 76 is deposited over ILD 52 and over gate masks 74. The respective process is illustrated as process 230 in the process flow 200 shown as in FIG. 34. An etch stop layer (not shown), may be, or may not be, deposited before the formation of ILD 76. In accordance with some embodiments, ILD 76 is formed through FCVD, CVD, PECVD, or the like. ILD 76 is formed of a dielectric material, which may be selected from silicon oxide, PSG, BSG, BPSG, USG, or the like.

In FIGS. 33A and 33B, ILD 76, ILD 52, CESL 50, and gate masks 74 are etched to form recesses (occupied by contact plugs 80A and 80B) exposing surfaces of source/drain regions 48 and/or gate stacks 70. The recesses may be formed through etching using an anisotropic etching process(es), such as RIE, NBE, or the like.

After the recesses are formed, silicide regions 78 are formed over source/drain regions 48. The respective process is illustrated as process 232 in the process flow 200 shown as in FIG. 34. Contact plugs 80B are then formed over silicide regions 78. Also, contacts 80A (may also be referred to as gate contact plugs) are formed in the recesses, and are over and contacting gate electrodes 68. The respective process is illustrated as process 234 in the process flow 200 shown as in FIG. 34. Transistors 82A and 82B are thus formed. Although FIG. 33B illustrates that contact plugs 80A and 80B are in a same cross-section, in various embodiments, contact plugs 80A and 80B may be formed in different cross-sections, thereby reducing the risk of shorting with each other.

The embodiments of the present disclosure have some advantageous features. Continuous Polysilicon on Diffusion edge (CPODE) regions having rounded profiles at the line ends can suffer from device leakage. The ends of the continuous polysilicon on diffusion edge (CPODE) regions can include leakage pathways to the contacts to the source/drain regions. In some embodiments, the methods and structures of the present disclosure by cutting the ends of the continuous polysilicon on diffusion edge (CPODE) regions can remove the leakage pathways.

In accordance with some embodiments of the present disclosure, a method is described that includes forming a plurality of semiconductor regions having first lengthwise directions parallel to a first direction, forming a plurality of gate stacks having second lengthwise directions parallel to a second direction perpendicular to the first direction, wherein the plurality of gate stacks are on first portions of the plurality of semiconductor regions.

The method can further include etching the plurality of semiconductor regions to form a first plurality of openings, wherein the first plurality of openings separate the plurality of semiconductor regions into first shorter portions, and filling the first plurality of openings with a first dielectric material to form fin isolation regions. The method can further include forming an isolation interface region between the fin isolation regions and the gate stacks. In an embodiments, forming the isolation interface region between the fin isolation regions and the gate stacks includes forming a second plurality of openings at interfaces of the fin isolation regions and the gate stacks, and filling the second plurality of openings with a second dielectric. In an embodiment, the method further includes etching the plurality of gate stacks to form a third plurality of openings, wherein the third plurality of openings separate the plurality of gate stacks into second shorter portions. In an embodiment, the method further includes filling the third plurality of openings with a third dielectric. In an embodiment, the isolation interface region has a planar end face. In an embodiment, the isolation interface region include convex curvature protrusions extending towards the gate stacks. In an embodiment, the isolation interface region includes a dielectric selected from the group consisting of hafnium oxide, silicon oxynitride, zirconium dioxide and combinations thereof.

In accordance with some embodiments of the present disclosure, a structure is described that includes a plurality of semiconductor layers, a plurality of gate stack on a portion of the plurality of semiconductor layers, the plurality of gate stacks having a gate length perpendicular to a length of the semiconductor layers, and a plurality of fin isolation regions present through the plurality of semiconductor layers, the plurality of fin isolation regions having a lengthwise direction perpendicular to the length of the semiconductor layers. The lengthwise direction of the plurality of fin isolation regions is aligned to the gate length. The structure further includes an isolation interface region between at least one of the plurality of fin isolation regions and the plurality of gate structures. In some embodiments, the structure further includes source/drain regions adjacent to the plurality of semiconductor layers. In some embodiments, the plurality of semiconductor layers are nanostructures. In some embodiments, the isolation interface comprises a first dielectric material, and the plurality of fin isolation regions comprises a second dielectric material, wherein the first dielectric material is different than the second dielectric material. In some embodiments, the structure further includes gate structure isolation regions present through the plurality of gate structures. In some embodiments, the gate structure isolation regions include a third dielectric material that is a same composition as the first dielectric material. In some embodiments, the gate structure isolation regions include a third dielectric material that is a different composition as the first dielectric material.

In accordance with some embodiments of the present disclosure, a structure is described that includes a plurality of semiconductor layers, and a plurality of gate stack on a portion of the plurality of semiconductor layers. The plurality of gate stacks have a gate length perpendicular to a length of the semiconductor layers. The structure can include a plurality of fin isolation regions present through the plurality of semiconductor layers, the plurality of fin isolation regions having a lengthwise direction perpendicular to the length of the semiconductor layers. The lengthwise direction of the plurality of fin isolation regions is aligned to the gate length. The device can include an isolation interface region between at least one of the plurality of fin isolation regions and the plurality of gate structures. The isolation interface regions can include a planar face abutting the plurality of fin isolation regions on a first sidewall, and convex protrusions extending into the plurality of gate structures from a second sidewall. In some embodiments, the structure includes source/drain regions adjacent to the plurality of semiconductor layers. In some embodiments, the plurality of semiconductor layers are nanostructures. In some embodiments, the isolation interface region includes a first dielectric material, and the plurality of fin isolation regions includes a second dielectric material, wherein the first dielectric material is different than the second dielectric material. In some embodiments, the gate structure isolation regions are present through the plurality of gate structures. In some embodiments, the gate structure isolation regions include a third dielectric material that is a same composition as the first dielectric material.

The foregoing outlines features of several embodiments so that those skilled in the art may better understand the aspects of the present disclosure.

Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a plurality of semiconductor regions having first lengthwise directions parallel to a first direction;
forming a plurality of gate stacks having second lengthwise directions parallel to a second direction perpendicular to the first direction, wherein the plurality of gate stacks are on first portions of the plurality of semiconductor regions;
etching the plurality of semiconductor regions to form a first plurality of openings, wherein the first plurality of openings separate the plurality of semiconductor region into first shorter portions;
filling the first plurality of openings with a first dielectric material to form fin isolation regions; and
forming an isolation interface region between the fin isolation regions and the gate stacks.

2. The method of claim 1, wherein forming the isolation interface region between the fin isolation regions and the gate stacks comprises:
forming a second plurality of openings at interfaces of the fin isolation regions and the gate stacks; and
filling the second plurality of openings with a second dielectric.

3. The method of claim 1 further comprising etching the plurality of gate stacks to form a third plurality of openings, wherein the third plurality of openings separate the plurality of gate stacks into second shorter portions.

4. The method of claim 3 further comprising filling the third plurality of openings with a third dielectric.

5. The method of claim 1, wherein the isolation interface region has a planar end face.

6. The method of claim 1, wherein the isolation interface region include convex curvature protrusions extending towards the gate stacks.

7. The method of claim 1, wherein the isolation interface region comprises a dielectric selected from the group consisting of hafnium oxide, silicon oxynitride, or zirconium dioxide.

8. A structure comprising:
a plurality of semiconductor layers;
a plurality of gate stacks on a portion of the plurality of semiconductor layers, the plurality of gate stacks having a gate length perpendicular to a length of the semiconductor layers;
a plurality of fin isolation regions present through the plurality of semiconductor layers, the plurality of fin isolation regions having a lengthwise direction perpendicular to the length of the semiconductor layers, wherein the lengthwise direction of the plurality of fin isolation regions is aligned to the gate length; and
an isolation interface region between at least one of the plurality of fin isolation regions and the plurality of gate stacks.

9. The structure of claim 8 further comprising source/drain regions adjacent to the plurality of semiconductor layers.

10. The structure of claim 8, wherein the plurality of semiconductor layers are nanostructures.

11. The structure of claim 8, wherein the isolation interface region comprises a first dielectric material, and the plurality of fin isolation regions comprises a second dielectric material, wherein the first dielectric material is different than the second dielectric material.

12. The structure of claim 11, further comprising gate structure isolation regions present through the plurality of gate stacks.

13. The gate structure of claim 12, wherein the gate structure isolation regions comprise a third dielectric material that is a same composition as the first dielectric material.

14. The gate structure of claim 12, wherein the gate structure isolation regions comprise a third dielectric material that is a different composition as the first dielectric material.

15. A structure comprising:
a plurality of semiconductor layers;
a plurality of gate structures on a portion of the plurality of semiconductor layers, the plurality of gate structures having a gate length perpendicular to a length of the semiconductor layers;
a plurality of fin isolation regions present through the plurality of semiconductor layer, the plurality of fin isolation regions having a lengthwise direction perpendicular to the length of the semiconductor layers, wherein the lengthwise direction of the plurality of fin isolation regions is aligned to the gate length; and
an isolation interface region between at least one of the plurality of fin isolation regions and the plurality of gate structures, wherein the isolation interface regions comprises a planar end face abutting the plurality of fin isolation regions on a first sidewall, and convex protrusions extending into the plurality of gate structures from a second sidewall.

16. The structure of claim 15 further comprising source/drain regions on the plurality of semiconductor layers.

17. The structure of claim 15, wherein the plurality of semiconductor layers are nanostructures.

18. The structure of claim 15, wherein the isolation interface region comprises a first dielectric material, and the plurality of fin isolation regions comprises a second dielectric material, wherein the first dielectric material is different than the second dielectric material.

19. The structure of claim 18 further comprising gate structure isolation regions present through the plurality of gate structures.

20. The structure of claim 19, wherein the gate structure isolation regions comprise a third dielectric material that is a same composition as the first dielectric material.
